(19) United States
(12) Patent Application Publication
(10) Pub. No.: US 2024/0243441 A1
(43) Pub. Date: Jul. 18, 2024

(54) RECHARGEABLE BATTERY MODULE

(71) Applicant: SAMSUNG SDI CO., LTD., Yongin-si (KR)

(72) Inventors: Young-Hwan KWON, Yongin-si (KR); Hyeok LEE, Yongin-si (KR)

(21) Appl. No.: 18/487,976

(22) Filed: Oct. 16, 2023

(30) Foreign Application Priority Data
Jan. 16, 2023 (KR) 10-2023-0006358

(51) Int. Cl. H01M 50/519; H01M 50/209; H01M 50/505; H01M 50/528; H01M 50/569; H05K 1/02

(52) U.S. Cl. CPC H01M 50/519; H01M 50/209; H01M 50/505; H01M 50/528; H01M 50/569; H05K 1/028; H05K 2201/10037; H05K 2201/10272

(57) ABSTRACT

A rechargeable battery module includes a plurality of battery cells stacked in a first direction; a bus bar holder covering the battery cells and exposing electrode terminals of the battery cells in a third direction crossing a second direction, wherein the electrode terminals are exposed at both sides of the bus bar holder along the second direction crossing the first direction; a bus bar connecting the electrode terminals to a bus bar support portion of the bus bar holder; a flexible printed circuit (FPC) on the bus bar and including a copper foil having one surface exposed in the third direction; an aluminum tab on another surface of the copper foil; and a welding portion including a laser welded portion of each of the bus bar, the copper foil, and the aluminum tab.

### CROSS-REFERENCE TO RELATED APPLICATION

The present application claims priority to and the benefit of Korean Patent Application No. 10-2023-0006358 filed on Jan. 16, 2023, in the Korean Intellectual Property Office, the entire content of which is hereby incorporated by reference.

### BACKGROUND

### 1. Field

Embodiments of the present disclosure relate to a rechargeable battery module.

### 2. Description of Related Art

Rechargeable batteries are a batteries that are repeatedly charged and discharged, unlike primary batteries. Small-capacity rechargeable batteries are used in portable small electronic devices, such as mobile phones, laptop computers, and camcorders.

Large-capacity and high-density rechargeable batteries are used as power sources or energy storage for driving motors of hybrid vehicles and electric vehicles. A rechargeable battery may be used as a rechargeable battery module including a plurality of battery cells connected in series and/or in parallel to be able to drive a motor of a hybrid vehicle, as an example, that requires a relatively high energy density.

For example, a rechargeable battery module may use an intermediate medium made of a nickel tab to connect a flexible printed circuit (FPC) and a bus bar made of aluminum or copper to measure cell voltage.

In a case of using the nickel tab as the intermediate medium, one end of the nickel tab is connected to the flexible printed circuit by a soldering method, and the other end of the nickel tab is connected to the bus bar by a laser welding method. The method of using the nickel tab increases the price of raw materials and reduces the cost competitiveness of the rechargeable battery module.

### SUMMARY

Aspects of one or more embodiments of the present disclosure are directed toward to a rechargeable battery module that may directly laser-weld a bus bar and a sensing flexible printed circuit (FPC).

Aspects of one or more embodiments of the present disclosure are directed toward a rechargeable battery module that may improve cost competitiveness by removing expensive nickel tabs by directly welding a flexible printed circuit (FPC) and a bus bar and reducing the process cost.

Aspects of one or more embodiments of the present disclosure are directed toward a rechargeable battery module that may prevent cost increase by using a flexible printed circuit (FPC) of 1 ounce (1 oz=35 μm) of copper foil, which is most commonly used for general purposes.

Aspects of one or more embodiments of the present disclosure are directed toward a rechargeable battery module that may directly laser-weld a flexible printed circuit that utilizes a general-purpose copper foil to an aluminum bus bar and that may secure stable welding strength.

Additional aspects will be set forth in part in the description which follows and, in part, will be apparent from the description, or may be learned by practice of the presented embodiments of the disclosure.

One or more embodiments of the present disclosure provides a rechargeable battery module including: a plurality of battery cells stacked in a first direction; a bus bar holder covering the battery cells and exposing electrode terminals of the battery cells in a third direction crossing a second direction, wherein the electrode terminals are exposed at both sides of the bus bar holder along the second direction crossing the first direction; a bus bar connecting the electrode terminals to a bus bar support portion of the bus bar holder; a flexible printed circuit (FPC) on the bus bar and including a copoer foil having one surface exposed in the third direction; an aluminum tab on another surface of the copper foil (e.g., opposite the one surface); and a welding portion including a laser welded portion of each of the bus bar, the copper foil, and the aluminum tab.

In one or more embodiments, the copper foil may have a thickness of 35 μm. The aluminum tab may have a thickness of 0.1 mm to 0.2 mm.

In one or more embodiments, the flexible printed circuit may include a signal line to transmit a sensing signal, a connection line connecting the copper foil to the signal line, a coating layer covering the signal line, the copper foil, and the connection line, and a slot hole that surrounds (e.g., is around) an outer periphery of the copper foil, that extends through the coating layer, and that has two ends, wherein, in the first direction, one end of the slot hole is on one side of the connection line and the other end of the slot hole is on an opposite side of the connection line.

In one or more embodiments, the signal line may extend along the first direction from one side of the flexible printed circuit, the one side of the flexible printed circuit extending along the second direction, and the copper foil may be at another side of the flexible printed circuit in the second direction.

In one or more embodiments, the connection line may extend along the second direction connecting the signal line and the copper foil.

The coating layer may include a neck portion between the two ends of the slot hole.

In one or more embodiments, a width of the neck portion in the first direction may be smaller than an entire length of the slot hole in the first direction and larger than a width of the connecting line in the first direction.

In one or more embodiments, the bus bar may include a terminal connection portion connecting electrode terminals of adjacent ones of the battery cells in the first direction, and a sensing portion protruding in the second direction from one side of the terminal connection portion and connected to the copper foil.

In one or more embodiments, the sensing portion may have an area (L1*L2) of a first length (L1) in the first direction and a second length (L2) in the second direction, and the area of the sensing portion may overlap an entire area of each of the copper foil, the slot hole, and the connection line, and a part of the signal line.

In one or more embodiments, the welding portion may include a mixture of aluminum of the bus bar, copper of the copper foil, and aluminum of the aluminum tab.

In one or more embodiments, the copper foil may include a nickel (Ni) plating section and a gold (Au) plating section. The mixture of the welding portion may further include nickel (Ni) and gold (Au).

In one or more embodiments, the welding portion may be formed by laser welding with an output of 1 kW or less.

In one or more embodiments, if (e.g., when) the output of the laser welding is 180 W, a thickness of the copper foil is 35 μm, and a thickness of the aluminum tab is 0.2 mm, the welding portion may include 90.4 wt % of aluminum, 0.8 wt % of nickel, 4.4 wt % of copper, and 4.4 wt % of oxygen.

In one or more embodiments, if (e.g., when) the output of the laser welding is 210 W, a thickness of the copper foil is 35 μm, and a thickness of the aluminum tab is 0.2 mm, the welding portion may include 87.9 wt % of aluminum, 1.8 wt % of nickel, 7.4 wt % of copper, and 2.9 wt % of oxygen.

In one or more embodiments, if (e.g., when) the output of the laser welding is 240 W, a thickness of the copper foil is 35 μm, and a thickness of the aluminum tab is 0.2 mm, the welding portion may include 70.3 wt % of aluminum, 5.2 wt % of nickel, 22.2 wt % of copper, and 2.3 wt % of oxygen.

In one or more embodiments, the welding portion may include 70.3 to 90.4 wt % of aluminum, 0.8 to 5.2 wt % of nickel, 4.4 to 22.2 wt % of copper, and 2.3 to 4.4 wt % of oxygen.

The rechargeable battery module according to one or more embodiments of the present disclosure, by disposing a copper foil of a flexible printed circuit (FPC) on a bus bar and further providing an aluminum tab on the copper foil to form a welded portion by laser welding, the flexible printed circuit may be directly welded to the bus bar. Accordingly, because expensive nickel tabs are removed and process prices are lowered, cost competition may be improved.

According to one or more embodiments, because a general-purpose flexible printed circuit (FPC) with a 1 oz copper foil (1 oz=35 μm) is used, laser welding may be directly performed on an aluminum bus bar, and cost increases while securing stable welding strength may be prevented or reduced.

### BRIEF DESCRIPTION OF THE DRAWINGS

FIG. 1 illustrates an exploded perspective view of a rechargeable battery module according to one or more embodiments of the present disclosure.

FIG. 2 illustrates a perspective view of a part of FIG. 1, according to one or more embodiments of the present disclosure.

FIG. 3 illustrates a top plan view of a flexible printed circuit applied in FIG. 2 according to one or more embodiments of the present disclosure.

FIG. 4 illustrates a top plan view of a state in which a flexible printed circuit and an aluminum tab are disposed on a bus bar, according to one or more embodiments of the present disclosure.

FIG. 5 illustrates an exploded perspective view of the bus bar, the flexible printed circuit, and the aluminum tab shown in FIG. 4, according to one or more embodiments of the present disclosure.

FIG. 6 illustrates a cross-sectional view taken along line VI-VI of FIG. 5, according to one or more embodiments of the present disclosure.

FIG. 7 illustrates a top plan view of Comparative Example 1.

FIG. 8 illustrates a cross-sectional view taken along line VII-VII of FIG. 7.

FIG. 9 is a planar image of a result of Comparative Example 1 of FIG. 7 and FIG. 8.

FIG. 10a and FIG. 10b are each an image of a welded portion of a copper foil and a bus bar according to Comparative Example 2.

FIG. 11a and FIG. 11b are each an image of a welded portion of a copper foil and a bus bar according to Comparative Example 3.

FIG. 12a and FIG. 12b are each an image of a welded portion of a copper foil and a bus bar according to Comparative Example 4.

FIG. 13a and FIG. 13b are each an image of a welded portion of a copper foil and a bus bar according to Comparative Example 5.

FIG. 14a and FIG. 14b are each an image of a welded portion of a copper foil and a bus bar according to Comparative Example 6.

FIG. 15a and FIG. 15b are each an image of a welded portion of a copper foil and a bus bar according to Comparative Example 7.

FIG. 16 is a cross-sectional image of an example of the present disclosure before welding.

FIG. 17 is a cross-sectional image of a state after welding of FIG. 16.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

The illustrated embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

The drawings and description are to be regarded as illustrative in nature and not restrictive. Like reference numerals designate like elements throughout the specification, and thus duplicative descriptions thereof may not be provided.

In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” or “connected to” another element or layer, it can be directly on or connected to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

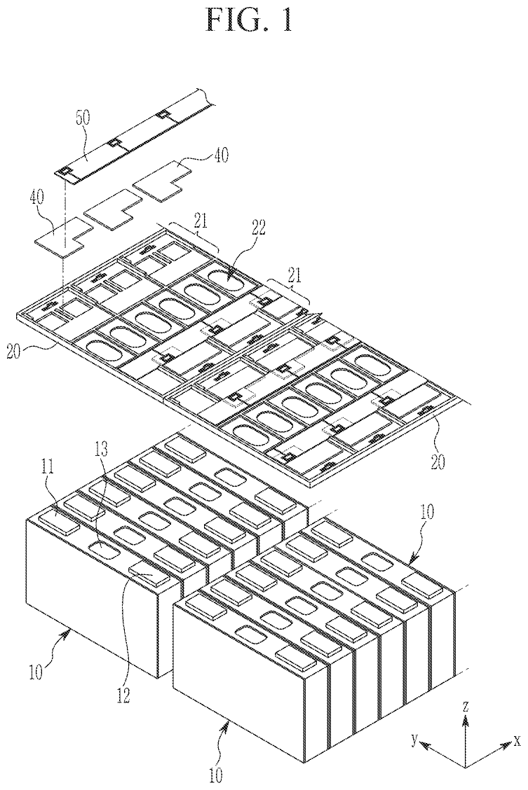

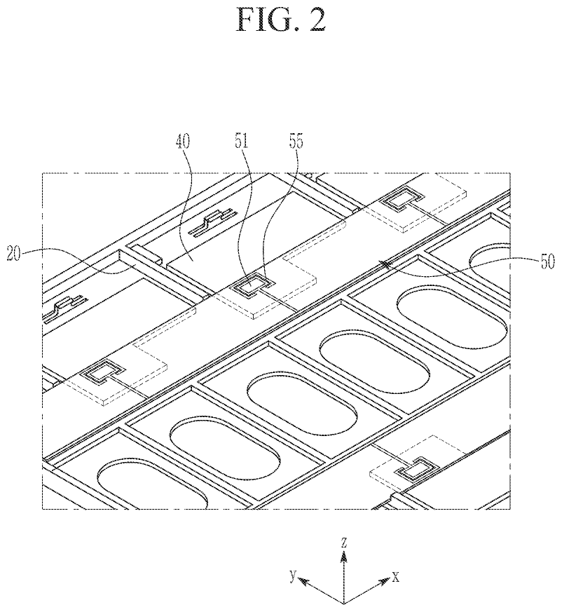

FIG. 1 illustrates an exploded perspective view of a rechargeable battery module according to one or more embodiments of the present disclosure, and FIG. 2 illustrates a perspective view of a part of FIG. 1, according to one or more embodiments of the present disclosure.

Referring to FIG. 1 and FIG. 2, a rechargeable battery module of one or more embodiments include a plurality of battery cells 10, a bus bar holder 20, a bus bar 40, and a flexible printed circuit (FPC) 50.

The flexible printed circuit 50, which is used for general purpose, includes a copper foil 51, and a thickness of the copper foil 51 is 35 μm, equivalent to 1 oz. The copper foil 51 of 1 ounce or more is not widely used because it significantly increases the cost of the flexible printed circuit 50.

In terms of welding characteristics, if (e.g., when) a thickness of the copper foil 51 is 100 μm, it has excellent welding characteristics, but if (e.g., when) the thickness of the copper foil 51 is less than 100 μm, the welding strength is low and laser welding is not easy. In one or more embodiments, stable welding strength may be realized even in the flexible printed circuit 50 using the copper foil 51 having a thickness of 35 μm, which is used for general purposes.

The rechargeable battery module according to one or more embodiments may have frames having various structures, but a detailed description of these structures may not be provided, and a structure including main portions of the embodiments of the present disclosure will be described.

The plurality of battery cells 10 are formed as rechargeable batteries and are stacked in a first direction (x-axis direction). A pair of end plates are disposed at both ends of the stacked battery cells 10 in the first direction to set constraints on the battery cells 10 in the first direction (x-axis direction).

A pair of side plates are disposed at both sides of the battery cells 10 in a second direction (y-axis direction) crossing the first direction and are connected to the pair of end plates to set constraints on the battery cells 10 in the second direction.

The bus bar holder 20 includes a bus bar support portion 21 for connecting and insulating electrode terminals 11 and 12 of the battery cells 10 (e.g., for connecting adjacent electrode terminals 10 or adjacent electrode terminals 11 and insulating electrode terminals 10 from electrode terminals 11) and a vent portion 22 for discharging vent gas from the battery cells 10.

The bus bar support portion 21 covers the battery cells 10 while exposing the electrode terminals 11 and 12 in a third direction (cell height, z-axis direction). The third direction (cell height, z-axis direction) crosses the first direction (cell thickness, x-axis direction) and the second direction (cell length, y-axis direction).

The bus bar 40 is welded to the electrode terminals 11 and 12 exposed in the third direction through the bus bar support portion 21 to electrically and mechanically connect the electrode terminals 11 and 12 (e.g., to electrically and mechanically connect adjacent electrode terminals 11 or adjacent electrode terminals 12). That is, the bus bar 40 connects the electrode terminals 11 and 12 of the battery cells 10 adjacent to each other in the first direction in parallel or in series.

The vent portion 22 corresponds to vents 13 of the battery cells 10 to discharge opening pressure and ejected materials of the battery cells 10 to the outside of the bus bar holder 20 when the vents 13 are opened. The bus bar support portions 21 corresponding to the electrode terminals 11 and 12 in the second direction (cell length, y-axis direction) are disposed on both sides of the bus bar holder 20 (e.g., at both ends or both sides of the bus bar holder 20 along the second direction), and the vent portion 22 corresponding to the vent 13 provided between the electrode terminals 11 and 12 is disposed between the bus bar support portions 21.

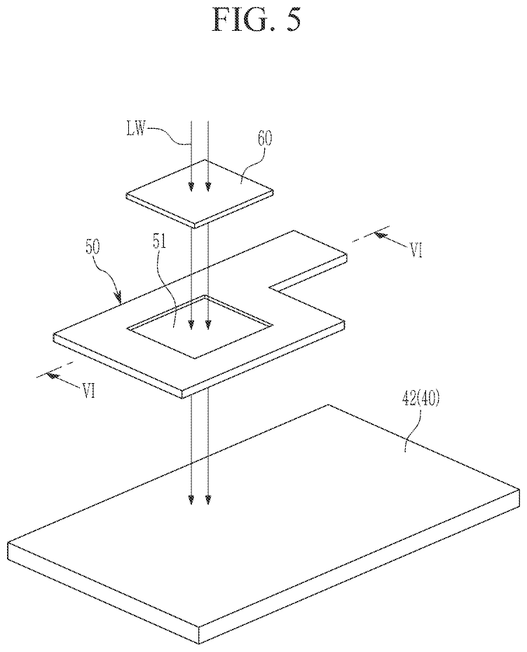

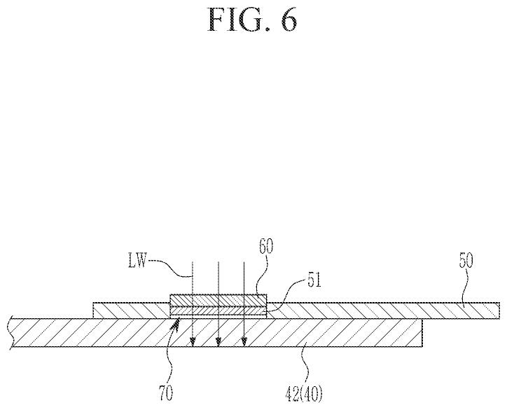

The flexible printed circuit 50 is disposed on the bus bar 40 with one surface of the copper foil 51 exposed in the third direction (z-axis). The aluminum tab 60 (see, e.g., FIGS. 5 and 6) is disposed on the other surface of the copper foil portion 51 and laser welded (LW). The welding portion 70 (see, e.g., FIG. 6) is formed of the bus bar 40, the copper foil 51, and the aluminum tab 60 subjected to laser welding (LW) by laser welding (LW).

For example, the copper foil 51 has a thickness of 1 ounce (oz, 35 μm) applied to the general-purpose flexible printed circuit 50. The aluminum tab 60 may have a thickness of 0.1 to 0.2 mm.

If (e.g., when) the thickness of the aluminum tab 60 is less than 0.1 mm, it is difficult to secure the strength of the welded portion 70. If (e.g., when) the thickness of the aluminum tab 60 exceeds 0.2 mm, it is difficult to form the welding portion 70 with the aluminum tab 60 due to melting vaporization of the copper foil 51 as well as due to requiring an excessively high laser power.

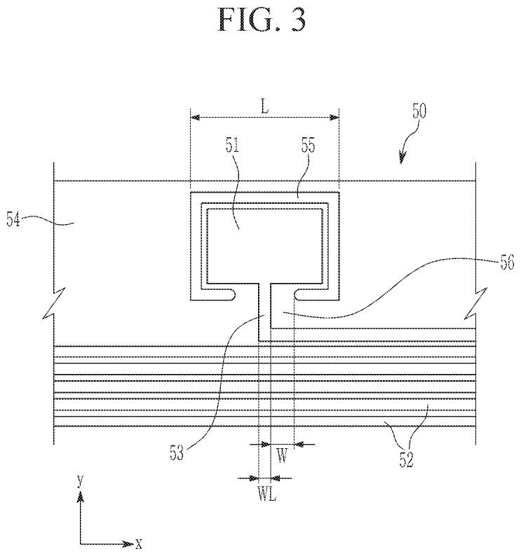

FIG. 3 illustrates a top plan view of the flexible printed circuit of FIG. 2, according to one or more embodiments of the present disclosure. Referring to FIG. 3, the flexible printed circuit 50 includes a signal line 52 for transmitting a sensing signal, a connection line 53, a coating layer 54, and a slot hole 55.

The connection line 53 connects the copper foil 51 to the signal line 52. The copper foil 51 is connected to the bus bar 40 by the welding portion 70 to detect the battery cell 10 connected to the bus bar 40 to transmit the detected signal to the connection line 53 and the signal line 52.

The coating layer 54 coats the signal line 52, the copper foil 51, and the connection line 53 to form the flexible printed circuit 50. As an example, the coating layer 54 is formed of polyimide and coated with an adhesive. The slot hole 55 surrounds the outer periphery of the copper foil 51 and penetrates the coating layer 54 (e.g., extends through the coating layer 54) to have both ends on both sides of the connection line 53 in a width direction (e.g., the x-axis direction) of the copper foil 51 (e.g., one end of the slot hole 55 is on one side of the connection line and the other end of the slot hole 55 is on an opposite side of the connection line in the width direction (e.g., the x-axis direction)).

The signal line 52 is formed in (e.g., extends along) the length direction (x-axis direction) of the flexible printed circuit 50 at (from) one side of the flexible printed circuit 50, the one side of the flexible printed circuit 50 extending along (in) the width direction (y-axis direction). The copper foil 51 is formed to have a predetermined area at the other side of the flexible printed circuit 50 (e.g., the copper foil 51 may be at the other side of the flexible printed circuit 50) in the width direction (y-axis direction). The connection line 53 is formed in (e.g., extends along) the width direction (y-axis direction) to connect the signal line 52 and the copper foil 51.

The coating layer 54 forms (e.g., includes) a neck portion 56 between the slot holes 55 on both sides of the connection line 53 in the length direction (x-axis direction). A width (W) of the neck portion 56 set in the length direction (x-axis direction) is smaller than a total length (L) of the slot hole 55 set in the length direction and larger than a width (WL) of the connection line 53.

Although the integrity of the copper foil 51 and the signal line 52 is weakened due to the slot hole 55, the width (W) of the neck portion 56 maintains the solid strength of the connection line 53, and it also allows the flow of the battery cell 10 to be absorbed into the slot hole 55.

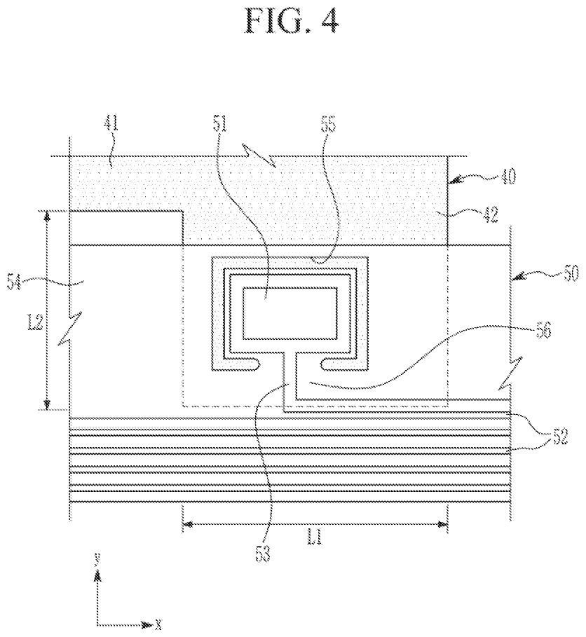

FIG. 4 illustrates a top plan view of a state in which a flexible printed circuit and an aluminum tab are disposed on a bus bar according to one or more embodiments of the present disclosure, FIG. 5 illustrates an exploded perspective view of the bus bar, the flexible printed circuit, and the aluminum tab shown in FIG. 4, according to one or more embodiments of the present disclosure, and FIG. 6 illustrates a cross-sectional view taken along line VI-VI of FIG. 5, according to one or more embodiments of the present disclosure.

Referring to FIG. 4 to FIG. 6, the bus bar 40 includes a terminal connection portion 41 and a sensing portion 42. The terminal connection portion 41 connects the electrode terminals 11 and 12 of the battery cells 10 adjacent to each other (e.g., connects adjacent electrode terminals 11 of the battery cells 10 or connects adjacent electrode terminals 12 of the battery cells 10) in the first direction (x-axis direction). The sensing portion 42 protrudes from one side of the terminal connection portion 41 in the second direction (y-axis direction) to be connected to the copper foil 51.

The sensing portion 42 has an area (L1*L2) of a first length L1 in the first direction (x-axis direction) and a second length L2 in the second direction (y-axis direction). The entire area of the copper foil 51, the slot hole 55, the connection line 53, and a portion of the signal line 52 are supported by the sensing portion 42 (e.g., the area (L1*L2) overlaps and entire area of each of the copper foil 51, the slot hole 55, and the connection line 53, and a part of the signal line 52.

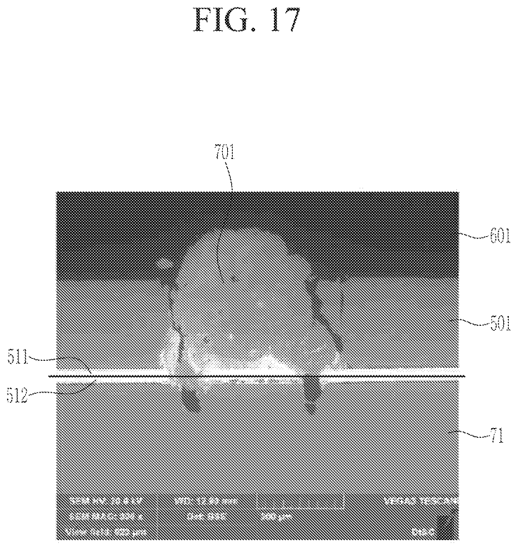

The welding portion 70 forms a structure in which (e.g., is a mixture of) the aluminum component of the bus bar 40, the copper component of the copper foil 51, and the aluminum component of the aluminum tab 60 are mixed (see FIG. 17). Therefore, the welding portion 70 may weld the copper foil 51 and the bus bar 40 with sufficient strength.

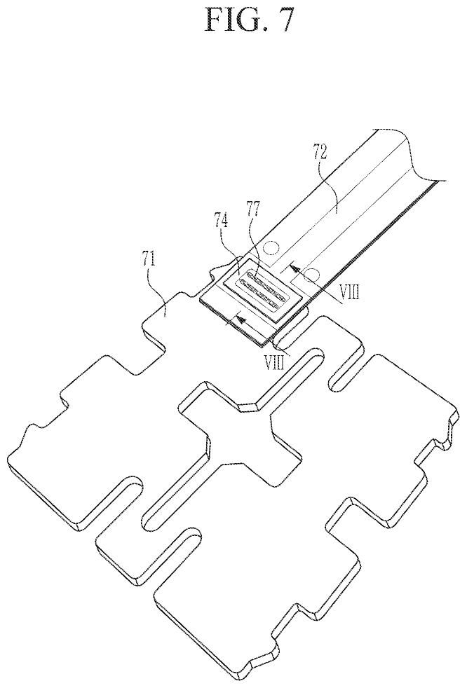

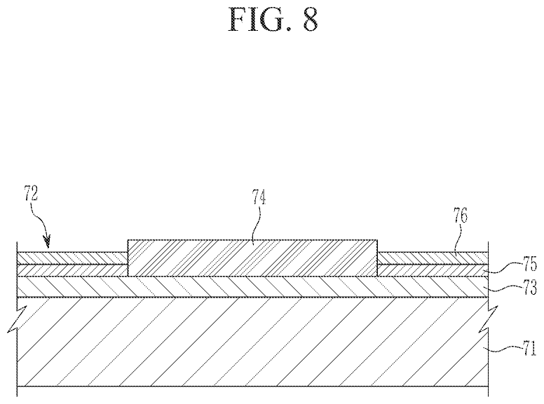

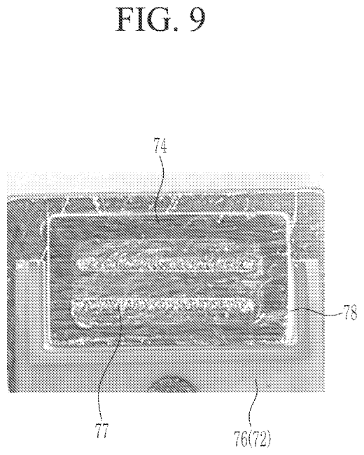

FIG. 7 illustrates a top plan view of Comparative Example 1, FIG. 8 illustrates a cross-sectional view taken along line VII-VII of FIG. 7, and FIG. 9 is a planar image of a result of Comparative Example 1 of FIG. 7 and FIG. 8.

Referring to FIG. 7 to FIG. 9, in Comparative Example 1, the copper foil 73 of the flexible printed circuit 72 is disposed on the aluminum bus bar 71, and an aluminum tab 74 is disposed on a copper foil 73 exposed in a coating layer 76 attached with an adhesive layer 75 and laser welded with a two-line bead 77.

If (e.g., when) the bus bar 71 and the flexible printed circuit 72 are stretched, and if (e.g., when) it is seen that the coating layer 76 of the flexible printed circuit 72 is first broken (78), it can be seen that weldability of the aluminum bus bar 71, the copper foil 73, and the aluminum tab 74 is suitable or excellent, while rigidity of the flexible printed circuit 72 is insufficient.

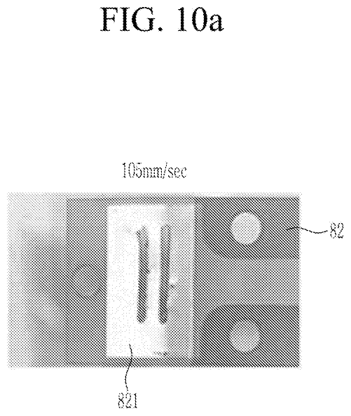

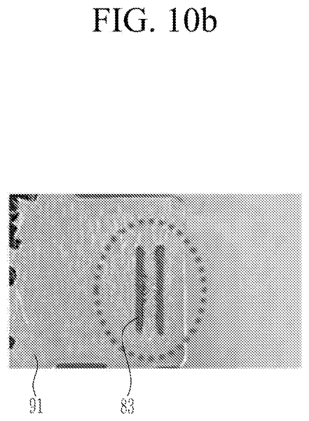

FIG. 10a and FIG. 10b are images of a welded portion of a copper foil and a bus bar according to Comparative Example 2. Referring to FIG. 10a and FIG. 10b, in Comparative Example 2, the copper foil 821 of the flexible printed circuit 82 was disposed on the aluminum bus bar 91, and laser welding was performed on the copper foil 821 as two-line beads 83. A thickness of the copper foil 821 was 1 ounce (oz, e.g., 35 μm), and the laser welding was performed at a welding speed of 105 mm/see without applying an aluminum tab. A welding defect occurred in the bus bar 91.

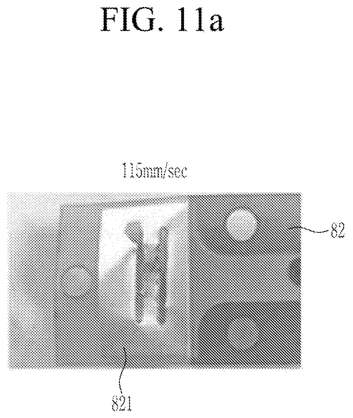

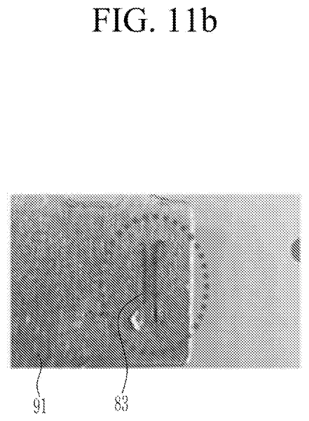

FIG. 11a and FIG. 11b are images of a welded portion of a copper foil and a bus bar according to Comparative Example 3. Referring to FIG. 11a and FIG. 11b, in Comparative Example 3, the thickness of the copper foil 821 was 1 oz, and the laser welding was performed at a welding speed of 115 mm/see without applying an aluminum tab. A welding defect occurred in the bus bar 91.

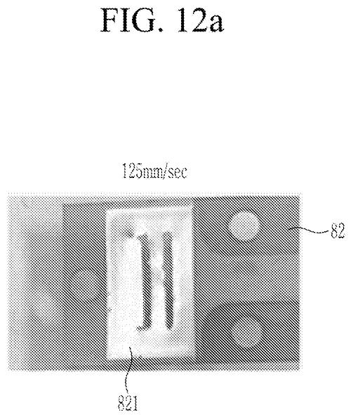

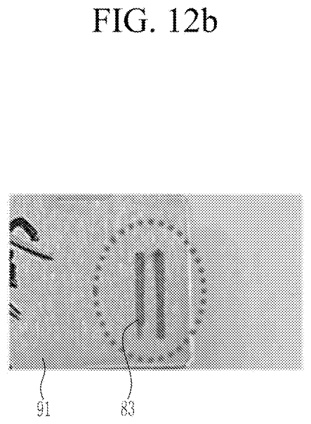

FIG. 12a and FIG. 12b are images of a welded portion of a copper foil and a bus bar according to Comparative Example 4. Referring to FIG. 12a and FIG. 12b, in Comparative Example 4, the thickness of the copper foil 821 was 1 oz, and the laser welding was performed at a welding speed of 125 mm/see without applying an aluminum tab. A welding defect occurred in the bus bar 91.

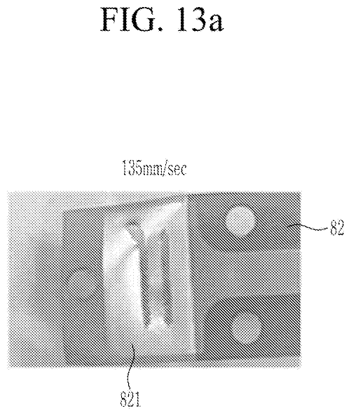

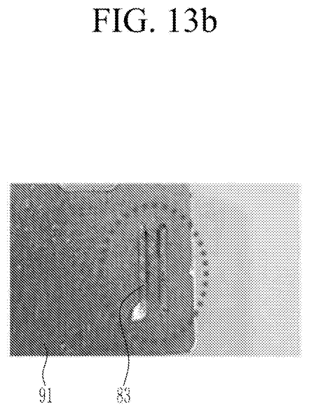

FIG. 13a and FIG. 13b are images of a welded portion of a copper foil and a bus bar according to Comparative Example 5. Referring to FIG. 13a and FIG. 13b, in Comparative Example 5, the thickness of the copper foil 821 was 1 oz, and the laser welding was performed at a welding speed of 135 mm/see without applying an aluminum tab. A welding defect occurred in the bus bar 91.

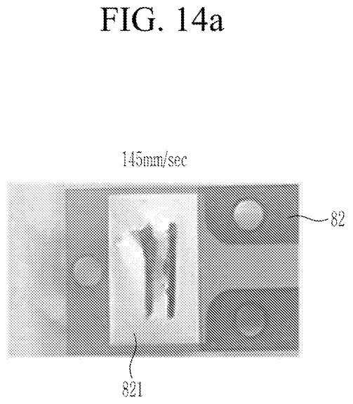

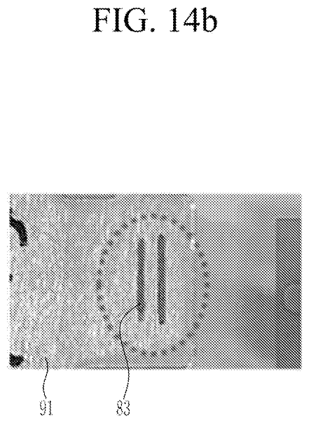

FIG. 14a and FIG. 14b are images of a welded portion of a copper foil and a bus bar according to Comparative Example 6. Referring to FIG. 14a and FIG. 14b, in Comparative Example 5, the thickness of the copper foil 821 was 1 oz, and the laser welding was performed at a welding speed of 145 mm/see without applying an aluminum tab. A welding defect occurred in the bus bar 91.

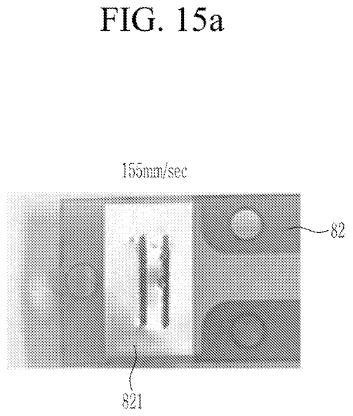

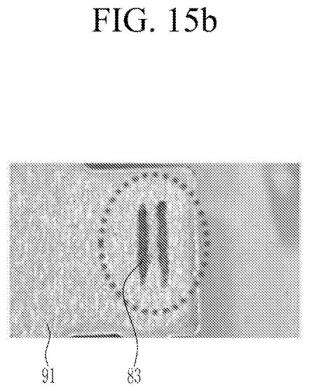

FIG. 15a and FIG. 15b are images of a welded portion of a copper foil and a bus bar according to Comparative Example 7. Referring to FIG. 15a and FIG. 15b, in Comparative Example 7, the thickness of the copper foil 821 was 1 oz, and the laser welding was performed at a welding speed of 155 mm/see without applying an aluminum tab. A welding defect occurred in the bus bar 91.

Referring to the welding defects that were the result of Comparative Examples 1 to 7 of FIG. 10a to FIG. 15b, it was found to be impossible or not practicable to weld the copper foil 821 having a thickness of 35 μm to the aluminum bus bar 91 without applying an aluminum tab. Even though the welding speed was varied, welding was impossible or not practicable.

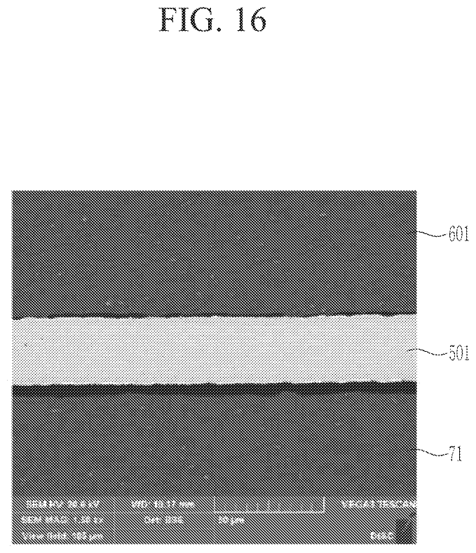

FIG. 16 is a cross-sectional image of an example of the present disclosure before welding, and FIG. 17 is a cross-sectional image of a state after the welding of FIG. 16.

Referring to FIG. 16 and FIG. 17, in the example, the copper foil 501 further includes a nickel (Ni) plating section 511 and a gold (Au) plating section 512 stacked in the thickness direction.

A stacked structure of the nickel (Ni) plating section 511 and the gold (Au) plating section 512 may be formed on lower and/or upper surfaces of the copper foil 501. If (e.g., when) the copper foil 501 of the flexible printed circuit is disposed on the aluminum bus bar 71, the aluminum tab 601 is disposed on the copper foil 501, and laser welding is performed, the welding part 701 has a structure in which nickel (Ni) and gold (Au) are further mixed with aluminum (AI).

Referring to the component analysis result of the welding portion 701, as shown in Table 1, it can be confirmed that all components of aluminum, copper, and nickel, which were representative components, were well mixed and that the more power (e.g., the higher the power) of the laser welding utilized, the more effectively they were mixed.

TABLE 1

| Test | Measuring | Component analysis result (unit: wt %) | | | | | | |
|---|---|---|---|---|---|---|---|---|
| sample | range | C | O | Al | Ni | Cu | Au | P |
| 180 W | AL Busbar | 18.3 | 8.3 | 73.3 | — | — | — | — |
| | Au plating section | — | 4.9 | 48.2 | 18.5 | 9.1 | 19.3 | — |
| | Copper foil | 16.9 | 1.0 | 29.8 | — | 52.4 | — | — |
| | Ni plating section | — | — | 38.4 | 51.2 | 5.9 | 0.4 | 4.1 |
| | Welding portion | — | 4.4 | 90.4 | 0.8 | 4.4 | — | — |
| 210 W | AL Busbar | — | 4.3 | 91.7 | — | 4.1 | — | — |
| | Au plating section | — | — | 47.0 | 37.1 | 8.3 | 7.7 | — |
| | Copper foil | — | — | 35.1 | — | 64.9 | — | — |
| | Ni plating section | — | — | 36.0 | 53.3 | 5.6 | — | 5.1 |
| | Welding portion | — | 2.9 | 87.9 | 1.8 | 7.4 | — | — |
| 240 W | AL Busbar | — | 6.4 | 89.7 | — | 4.0 | — | — |
| | Au plating section | — | — | 43.0 | 13.7 | 5.5 | 37.8 | — |
| | Copper foil | — | — | 38.1 | — | 61.9 | — | — |
| | Ni plating section | — | — | 36.5 | 51.3 | 6.3 | — | 5.9 |
| | Welding portion | — | 2.3 | 70.3 | 5.2 | 22.2 | — | — |

It can be confirmed that the metal components were well mixed in the welding portion 701, and there was no problem with the electrical characteristics (or reduced electrical issues), and the flexible printed circuit had sufficient tensile force, so the mechanical characteristics were also satisfied. The welding portion 701 may be formed using laser welding with an output of 1 kW or less, such as 180 W, 210 W, or 240 W.

In the first test sample, when the output of laser welding was 180 W, the thickness of the copper foil 501 was 35 μm, and the thickness of the aluminum tab 601 was 0.2 mm, the welding portion 701 included 90.4 wt % of aluminum, 0.8 wt % of nickel, 4.4 wt % of copper, and 4.4 wt % of oxygen.

In the second test sample, when the output of laser welding was 210 W, the thickness of the copper foil 501 was 35 μm, and the thickness of the aluminum tab 601 was 0.2 mm, the welding portion 701 included 87.9 wt % of aluminum, 1.8 wt % of nickel, 7.4 wt % of copper, and 2.9 wt % of oxygen.

In the third test sample, when the output of laser welding was 240 W, the thickness of the copper foil 501 was 35 μm, and the thickness of the aluminum tab 601 was 0.2 mm, the welding portion 701 included 70.3 wt % of aluminum, 5.2 wt % of nickel, 22.2 wt % of copper, and 2.3 wt % of oxygen.

When the output of laser welding was 180 to 240 W, the welding portion 701 included 70.3 to 90.4 wt % of aluminum, 0.8 to 5.2 wt % of nickel, 4.4 to 22.2 wt % of copper, and 2.3 to 4.4 wt % of oxygen.

Referring to the first to third test samples, if (e.g., when) the aluminum tab 601, which is a thin medium of a substantially same component as the bus bar 71, is applied to the copper foil 501 of 1 ounce, it is possible to weld the copper foil 501 to the aluminum bus bar 71.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the singular forms “a,” “an” and “the” are intended to include the plural forms as well, unless the context clearly indicates otherwise. It will be further understood that the terms “comprises,” “comprising,” “includes,” “including,” “have,” and “having” when used in this specification, specify the presence of the stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The portable device, vehicle, and/or the battery, e.g., a battery controller, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

### REFERENCE NUMERALS

10: battery cells 11, 12: electrode terminal
13: vent 20: bus bar holder
21: bus bar support portion 22: vent portion
40: bus bar 41: terminal connection portion
42: sensing portion 50: flexible printed circuit (FPC)
51: copper foil 52: signal line
53: connection line 54: coating layer
55: slot hole 56: neck portion
60: aluminum tab 70: welding portion
71: bus bar 72: flexible printed circuit
73: copper foil 74: aluminum tab
75: adhesive layer 76: coating layer
77: 2-line beads 501: copper foil
511: nickel (Ni) plating section 512: gold (Au) plating section
601: aluminum tab 701: welding portion
L: entire length L1: first length
L2: second length W: width of neck portion
WL: width of connection line

What is claimed is:

1. A rechargeable battery module comprising:
a plurality of battery cells stacked in a first direction;
a bus bar holder covering the battery cells and exposing electrode terminals of the battery cells in a third direction crossing a second direction, wherein the electrode terminals are exposed at both sides of the bus bar holder along the second direction crossing the first direction;
a bus bar connecting the electrode terminals to a bus bar support portion of the bus bar holder;
a flexible printed circuit (FPC) on the bus bar and comprising a copper foil having one surface exposed in the third direction;
an aluminum tab on another surface of the copper foil opposite the one surface; and
a welding portion comprising a laser welded portion of each of the bus bar, the copper foil, and the aluminum tab.

2. The rechargeable battery module as claimed in claim 1, wherein the copper foil has a thickness of 35 μm.

3. The rechargeable battery module as claimed in claim 1, wherein the aluminum tab has a thickness of 0.1 mm to 0.2 mm.

4. The rechargeable battery module as claimed in claim 1, wherein the flexible printed circuit comprises:
a signal line to transmit a sensing signal,
a connection line connecting the copper foil to the signal line,
a coating layer covering the signal line, the copper foil, and the connection line, and
a slot hole around an outer periphery of the copper foil, that extends through the coating layer, and that has two ends, wherein, in the first direction, one end of the slot hole is on one side of the connection line and the other end of the slot hole is on an opposite side of the connection line.

5. The rechargeable battery module as claimed in claim 4, wherein the signal line extends along the first direction from one side of the flexible printed circuit, the one side of the flexible printed circuit extending along the second direction, and the copper foil is at another side of the flexible printed circuit in the second direction.

6. The rechargeable battery module as claimed in claim 5, wherein the connection line extends along the second direction connecting the signal line and the copper foil.

7. The rechargeable battery module as claimed in claim 6, wherein the coating layer comprises a neck portion between the two ends of the slot hole.

8. The rechargeable battery module as claimed in claim 7, wherein a width of the neck portion in the first direction is smaller than an entire length of the slot hole in the first direction and larger than a width of the connecting line in the first direction.

9. The rechargeable battery module as claimed in claim 4, wherein the bus bar comprises:
a terminal connection portion connecting electrode terminals of adjacent ones of the battery cells in the first direction, and
a sensing portion protruding in the second direction from one side of the terminal connection portion and connected to the copper foil.

10. The rechargeable battery module as claimed in claim 9, wherein the sensing portion has an area (L1*L2) of a first length (L1) in the first direction and a second length (L2) in the second direction, and the area of the sensing portion overlaps an entire area of each of the copper foil, the slot hole, and the connection line, and a part of the signal line.

11. The rechargeable battery module as claimed in claim 1, wherein the welding portion comprises a mixture of aluminum of the bus bar, copper of the copper foil, and aluminum of the aluminum tab.

12. The rechargeable battery module as claimed in claim 11, wherein the copper foil comprises a nickel (Ni) plating section and a gold (Au) plating section.

13. The rechargeable battery module as claimed in claim 12, wherein the mixture of the welding portion further comprises nickel (Ni) and gold (Au).

14. The rechargeable battery module as claimed in claim 13, wherein the welding portion is formed by laser welding utilizing an output of 1 kW or less.

15. The rechargeable battery module as claimed in claim 14, wherein, if the output of the laser welding is 180 W, a thickness of the copper foil is 35 μm, and a thickness of the aluminum tab is 0.2 mm, the welding portion comprises 90.4 wt % of aluminum, 0.8 wt % of nickel, 4.4 wt % of copper, and 4.4 wt % of oxygen.

16. The rechargeable battery module as claimed in claim 14, wherein, if the output of the laser welding is 210 W, a thickness of the copper foil is 35 μm, and a thickness of the aluminum tab is 0.2 mm, the welding portion comprises 87.9 wt % of aluminum, 1.8 wt % of nickel, 7.4 wt % of copper, and 2.9 wt % of oxygen.

17. The rechargeable battery module as claimed in claim 14, wherein, if the output of the laser welding is 240 W, a thickness of the copper foil is 35 μm, and a thickness of the aluminum tab is 0.2 mm, the welding portion comprises 70.3 wt % of aluminum, 5.2 wt % of nickel, 22.2 wt % of copper, and 2.3 wt % of oxygen.

18. The rechargeable battery module as claimed in claim 13, wherein the welding portion comprises 70.3 to 90.4 wt % of aluminum, 0.8 to 5.2 wt % of nickel, 4.4 to 22.2 wt % of copper, and 2.3 to 4.4 wt % of oxygen.
